(19) United States
(12) Patent Application Publication
(10) Pub. No.: US 2026/0029478 A1
(43) Pub. Date: Jan. 29, 2026

(54) Circuit Device And Electronic Apparatus

(71) Applicant: SEIKO EPSON CORPORATION, Tokyo (JP)

(72) Inventor: Kinya MATSUDA, Matsumoto (JP)

(21) Appl. No.: 19/282,350

(22) Filed: Jul. 28, 2025

(30) Foreign Application Priority Data
Jul. 29, 2024 (JP) 2024-121850

(51) Int. Cl. G01R 31/388; G01R 31/367; G01R 31/374; G01R 31/389; H02J 7/00

(52) U.S. Cl. CPC G01R 31/388; G01R 31/367; G01R 31/374; G01R 31/389; H02J 7/0048

(57) ABSTRACT

A circuit device includes a charging circuit configured to charge a battery, a voltage measurement circuit configured to measure a battery voltage of the battery, a storage unit configured to store weighting coefficients for a battery capacity in respective voltage sections of a plurality of voltage sections, and a control circuit configured to perform integration processing on the weighting coefficients based on a measurement result of the battery voltage by the voltage measurement circuit, and obtain a charge capacity of the battery charged by the charging circuit based on a result of the integration processing.

The present application is based on, and claims priority from JP Application Serial Number 2024-121850, filed Jul. 29, 2024, the disclosure of which is hereby incorporated by reference herein in its entirety.

### BACKGROUND

### 1. Technical Field

The present disclosure relates to a circuit device, an electronic apparatus, and so on.

### 2. Related Art

JP-A-2021-151144 discloses a charge-discharge control device that controls charge and discharge of a battery and obtains a charge capacity of the battery. In JP-A-2021-151144, a time from when a battery voltage exceeds a lower limit voltage value of each of voltage sections to when the battery voltage reaches an upper limit voltage value thereof is measured for each of the voltage sections, and a sectional charge capacity corresponding to each of the voltage sections is obtained based on a product of the measured time and a charging current value.

JP-A-2021-151144 is an example of the related art.

For example, in order to obtain the charge capacity of the battery, it has been necessary to dispose, between a circuit device for charging and the battery, a Coulomb counter for obtaining an amount of charge. However, when such a Coulomb counter is provided, a reduction in size and a reduction in cost of an electronic apparatus are hindered. In addition, in JP-A-2021-151144 described above, since the information of the battery capacity in each of the voltage sections is not stored in a storage unit, it is necessary to measure the time from when the voltage exceeds the lower limit voltage value of the voltage section to when the voltage reaches the upper limit voltage value thereof and the charging current value, and it is necessary to calculate the product of the time and the charging current value. Therefore, it has been unachievable to obtain the charge capacities of batteries having various capacity characteristics with processing light in load.

### SUMMARY

An aspect of the present disclosure relates to a circuit device including a charging circuit configured to charge a battery, a voltage measurement circuit configured to measure a battery voltage of the battery, a storage unit configured to store weighting coefficients for a battery capacity in respective voltage sections of a plurality of voltage sections, and a control circuit configured to perform integration processing on the weighting coefficients based on a measurement result of the battery voltage by the voltage measurement circuit, and obtain a charge capacity of the battery charged by the charging circuit based on a result of the integration processing.

Further, another aspect of the present disclosure relates to an electronic apparatus including the circuit device described above, and the battery.

### BRIEF DESCRIPTION OF THE DRAWINGS

FIG. 1 illustrates a configuration example of a circuit device and an electronic apparatus according to the present embodiment.

FIG. 2 illustrates a detailed configuration example of the circuit device and the electronic apparatus.

FIG. 3 shows a configuration example of a charging circuit.

FIG. 4 is a diagram illustrating storing setting information and weighting coefficients of voltage sections in a storage unit.

FIG. 5 is a diagram illustrating a method according to the present embodiment.

FIG. 6 is a flowchart illustrating operations according to the present embodiment.

FIG. 7 is a diagram illustrating an internal resistance and an open voltage of a battery.

FIG. 8 is a diagram illustrating a method of eliminating an influence of the internal resistance.

FIG. 9 is a diagram illustrating a method of measuring the internal resistance.

FIG. 10 is a flowchart illustrating a detailed operation of the present embodiment.

### DESCRIPTION OF EMBODIMENTS

The present embodiment will hereinafter be described. Note that the present embodiment described below does not unreasonably limit the description content of the appended claims. Further, all the configurations described in the embodiment are not necessarily essential elements.

### 1. Circuit Device and Electronic Apparatus

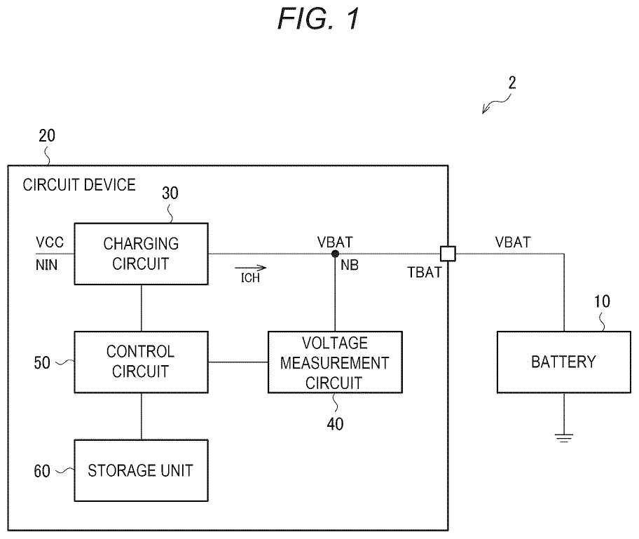

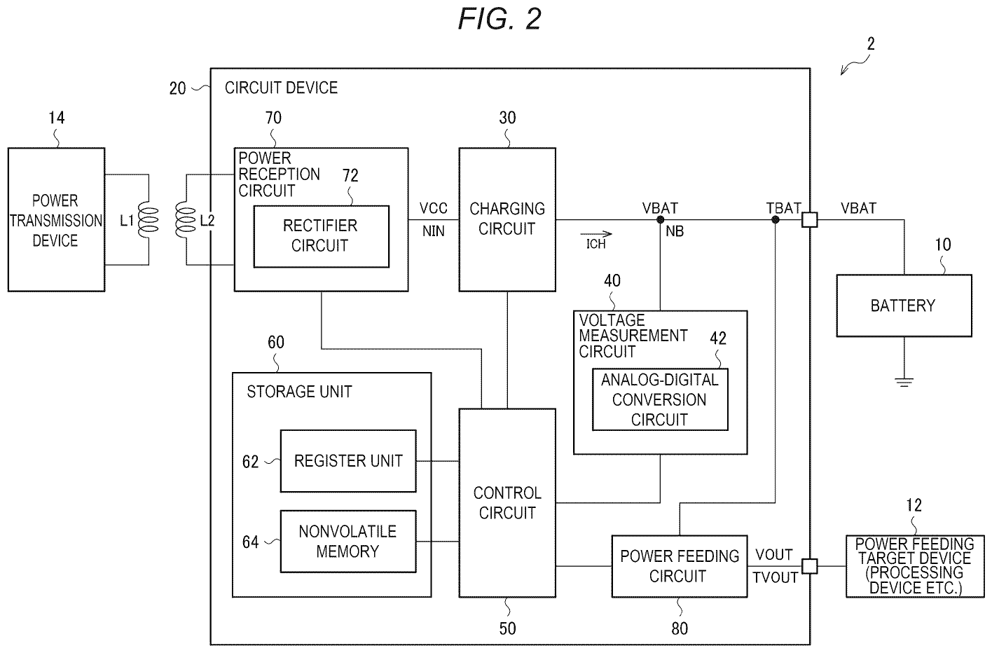

FIG. 1 illustrates a configuration example of a circuit device 20 and an electronic apparatus 2 in the present embodiment. The circuit device 20 includes a charging circuit 30, a voltage measurement circuit 40, a control circuit 50, and a storage unit 60. Further, the electronic apparatus 2 includes the circuit device 20 and a battery 10. Note that the circuit device 20 and the electronic apparatus 2 are not limited to the configuration in FIG. 2, and various modified implementations such as omission of some of the elements thereof or addition of other elements thereto can be made.

The electronic apparatus 2 is a hearable device such as a hearing aid or an earphone for audio listening, or a wearable device. The earphone is, for example, what is called a wireless earphone. Note that as the electronic apparatus 2, various apparatuses such as a head-mounted display, a portable communication terminal such as a smartphone or a mobile phone, a wristwatch, a biological information measurement apparatus, a shaver, an electric toothbrush, a wrist computer, a handy terminal, or an in-vehicle apparatus of an automobile can be assumed.

The circuit device 20 operates as, for example, a charging device that charges the battery 10. The circuit device 20 can be realized by, for example, an integrated circuit device called an IC. The battery 10 which is a charging target is, for example, a secondary battery, such as a lithium-ion secondary battery, a nickel-metal hydride battery, or a nickel-cadmium battery. Further, the battery 10 may be what is realized by a super capacitor or the like. The battery 10 is coupled to a terminal TBAT of the circuit device 20. The terminal TBAT is, for example, a pad or an external connection terminal of a package of the circuit device 20 which is an IC. For example, in a pad area, a metal layer is exposed from a passivation film that is an insulating layer, and the metal layer thus exposed constitutes the pad that is the terminal of the circuit device 20. Note that the coupling in the present embodiment is electrical coupling. The electrical coupling means coupling in which an electrical signal can be transmitted, and is coupling in which information can be transmitted with an electrical signal. The electrical coupling may be coupling through a passive element and the like.

The charging circuit 30 charges the battery 10. For example, the charging circuit 30 charges the battery 10 with received power by the power supply voltage VCC supplied to a power supply node NIN. For example, the charging circuit 30 generates a charging current ICH based on the power supply voltage VCC and supplies the charging current ICH to a node NB to thereby charge the battery 10. Specifically, the charging circuit 30 charges the battery 10 by constant-current charging or CCCV charging. The constant-current charging is CC charging. In the CCCV charging, the charging circuit 30 first performs the constant-current charging (the CC charging) of the battery 10, and then switches to constant-voltage charging (CV charging) to charge the battery 10. For example, the battery 10 is charged by constant-current charging, and when a battery voltage VBAT reaches a predetermined voltage, the constant-current charging is switched to the constant-voltage charging. Note that the power received due to the power supply voltage VCC may be power received using contactless power transmission as illustrated in FIG. 2 described later, or may be power received using contacted power transmission via wire. Further, the power supply voltage VCC is, for example, 5 V to 4 V, and a battery voltage VBAT is, for example, 4.3 V to 3.6 V.

The voltage measurement circuit 40 measures the battery voltage VBAT. The battery voltage VBAT is, for example, a voltage of a positive electrode of the battery 10. For example, the voltage measurement circuit 40 measures the battery voltage VBAT of the node NB which is a charging node of the battery 10. For example, the voltage measurement circuit 40 performs analog-digital conversion of the battery voltage VBAT and outputs digital data of the battery voltage VBAT obtained by the analog-digital conversion to the control circuit 50.

The storage unit 60 stores various types of information, and is realized by a storage circuit such as a memory or a register. Further, the storage unit 60 stores the weighting coefficient with respect to the battery capacity in each of a plurality of voltage sections. The voltage sections may also be referred to as voltage intervals or voltage range segments. The unit of the battery capacity is, for example, mAh. The voltage sections are sections into which a voltage variation of the battery voltage VBAT is divided. The voltage sections may be voltage sections at constant intervals or voltage sections at non-constant intervals. As an example, it is possible to adopt the voltage sections having narrower intervals in a range in which the change in the battery capacity with the battery voltage VBAT is large, than in a range in which the change in the battery capacity with the battery voltage VBAT is small. For example, since the change in the battery capacity with the battery voltage VBAT is larger in the voltage section VI1 than in the voltage section VI2, the voltage range of the voltage section VI1 is narrower than the voltage range of the voltage section VI2. Further, the weighting coefficient is information representing a ratio of the battery capacity estimated to be charged in each of the plurality of voltage sections. For example, the weighting coefficient is information representing a ratio of the battery capacity charged in each of the voltage sections to the battery capacity when fully charged. For example, the weighting coefficient is a coefficient which is weighted by the percentage of the battery capacity to be charged in each of the voltage sections assuming the battery capacity when fully charged as 100%, and is assigned. For example, the weighting coefficient in each of the voltage sections is set based on the charging characteristic which is the characteristic of the battery-voltage to the battery-capacity of the battery 10 to be used in the electronic apparatus 2, and the information of the weighting coefficient thus set is stored in the storage unit 60.

The control circuit 50 performs various types of control processing and arithmetic processing. For example, the control circuit 50 controls the charging circuit 30. The control circuit 50 can be realized by, for example, an application specific integrated circuit (ASIC) using automatic layout and wiring such as a gate array, but may be realized by a processor such as a digital signal processor (DSP), a central processing unit (CPU), or a microcontroller.

Further, the control circuit 50 performs integration processing on the weighting coefficients based on the measurement result of the battery voltage VBAT by the voltage measurement circuit 40. For example, the control circuit 50 reads, from the storage unit 60, the weighting coefficient in the voltage section to which the measured battery voltage VBAT belongs, and performs the processing of integrating the weighting coefficient thus read. Then, the control circuit 50 obtains, based on the result of the integration processing, the charge capacity of the battery 10 charged by the charging circuit 30. For example, it is assumed that the battery voltage VBAT measured when the charging of the battery 10 is started belongs to an i-th voltage section, and the battery voltage VBAT measured when the charging of the battery 10 is ended belongs to a j-th voltage section. The characters i and j are integers which satisfy i<j. On this occasion, the control circuit 50 reads the weighting coefficients of the i-th voltage section to the j-th voltage section from the storage unit 60 and then performs the integration processing thereon to obtain the charge capacity of the battery 10 charged by the charging circuit 30. In this case, the weighting coefficient in the i-th voltage section may be multiplied by an interpolation coefficient corresponding to the voltage ratio of the battery voltage VBAT (charging start voltage) in the i-th voltage section. Further, the weighting coefficient in the j-th voltage section may also be multiplied by an interpolation coefficient corresponding to the voltage ratio of the battery voltage VBAT (charging end voltage) in the j-th voltage section. Then, based on the charge capacity of the battery 10 obtained in this way, for example, update processing of cycle time representing the number of times of charging of the battery 10 is performed, or notification processing of displaying or giving notice of the charge capacity in the electronic apparatus 2 is performed.

FIG. 2 shows a detailed configuration example of the circuit device 20 and the electronic apparatus 2 in the present embodiment. FIG. 2 is a configuration example when performing wireless charging in which the battery 10 is charged based on the power received with contactless power transmission. In FIG. 2, the circuit device 20 includes a power reception circuit 70 and a power feeding circuit 80 in addition to the charging circuit 30, the voltage measurement circuit 40, the control circuit 50, and the storage unit 60. Note that the circuit device 20 and the electronic apparatus 2 are not limited to the configuration in FIG. 2, and various modified implementations such as omission of some of the elements thereof or addition of other elements thereto can be made.

The power reception circuit 70 receives transmitted power from a power transmission device 14 via contactless means. That is, power is received wirelessly. For example, a primary coil L1 is disposed at a power transmission device 14 side, and a secondary coil L2 is disposed at a power reception device side implemented by the circuit device 20. The power transmission device 14 is provided to, for example, a charging stand or a charging case that charges the electronic apparatus 2. Further, by a power transmission driver of the power transmission device 14 applying an AC voltage to the primary coil L1, the power is transmitted from the primary coil L1 to the secondary coil L2. The power reception circuit 70 receives the power from the power transmission device 14. Specifically, the power reception circuit 70 converts an AC induced voltage of the secondary coil L2 into a DC rectified voltage. This conversion is performed by a rectifier circuit 72 provided to the power reception circuit 70. The rectifier circuit 72 can be realized by, for example, a plurality of transistors or diodes. The charging circuit 30 charges the battery 10 based on the power supply voltage VCC which is the rectified voltage.

The voltage measurement circuit 40 includes an analog-digital conversion circuit 42. The analog-digital conversion circuit 42 performs analog-digital conversion of the battery voltage VBAT of the node NB and outputs digital data obtained by the analog-digital conversion to the control circuit 50.

The storage unit 60 includes a register unit 62 and a nonvolatile memory 64. However, the storage unit 60 may be what is realized by one of the register unit 62 and the nonvolatile memory 64. For example, the nonvolatile memory 64 may be disposed outside the circuit device 20, and in this case, the storage unit 60 includes only the register unit 62.

The register unit 62 stores various types of information. The control circuit 50 reads information such as data and commands stored in the register unit 62, and operates. The register unit 62 can be realized by, for example, flip-flop circuits or a memory such as a RAM.

The nonvolatile memory 64 is a memory that can maintain stored content even when no power is supplied from the outside. The nonvolatile memory 64 can be realized by, for example, an electrically erasable programmable read-only memory (EEPROM) in which data can be erased, a one time programmable (OTP) memory using a floating gate avalanche injection MOS (FAMOS) or the like.

The register unit 62 stores various types of information by, for example, loading the information read from the nonvolatile memory 64. Alternatively, it is possible to arrange that an interface circuit (not illustrated) is provided to the circuit device 20, and the register unit 62 stores the information input from the outside via the interface circuit. Alternatively, it is possible to arrange that a communication circuit (not illustrated) that communicates with the power transmission device 14 is provided to the circuit device 20, and the register unit 62 stores the information received from the power transmission device 14 by the communication circuit.

The power feeding circuit 80 performs a discharging operation of the battery 10 to supply a power supply voltage based on the discharging operation to a power feeding target device 12. The power feeding target device 12 is, for example, a processing device such as a microcomputer provided to the electronic apparatus 2. Specifically, the power feeding circuit 80 operates using the battery voltage VBAT of the battery 10 as a power supply voltage. Then, the power feeding circuit 80 outputs the output voltage VOUT based on the battery voltage VBAT as the power supply voltage of the power feeding target device 12. For example, the power feeding circuit 80 includes a charge pump circuit, a switching regulator circuit, or the like, and the charge pump circuit or the switching regulator circuit performs a charge pump operation or a switching regulation operation of stepping down the battery voltage VBAT, and supplies the output voltage VOUT obtained by stepping down the battery voltage VBAT to the power feeding target device 12.

The circuit device 20 is provided with a charging-system circuit and a discharging-system circuit. The charging-system circuit operates based on the received power and charges the battery 10 as the charging target. For example, the charging-system circuit is supplied with the received power with the power supply voltage VCC, and operates based on the power supply voltage VCC to charge the battery 10. Meanwhile, the discharging-system circuit operates based on the battery voltage VBAT of the battery 10. That is, each circuit provided to the discharging-system circuit operates using the battery voltage VBAT as a power supply voltage. The power feeding circuit 80 provided as the discharging-system circuit outputs the output voltage VOUT based on the battery voltage VBAT as the power supply voltage of the power feeding target device 12.

Further, the register unit 62 is the discharging-system circuit. Further, a control circuit for the charging system and a control circuit for the discharging system are provided as the control circuit 50. The register unit 62 and the control circuit for the discharging system are arranged to be able to operate with the battery voltage VBAT as the power supply voltage even when no power is received by the power reception circuit 70.

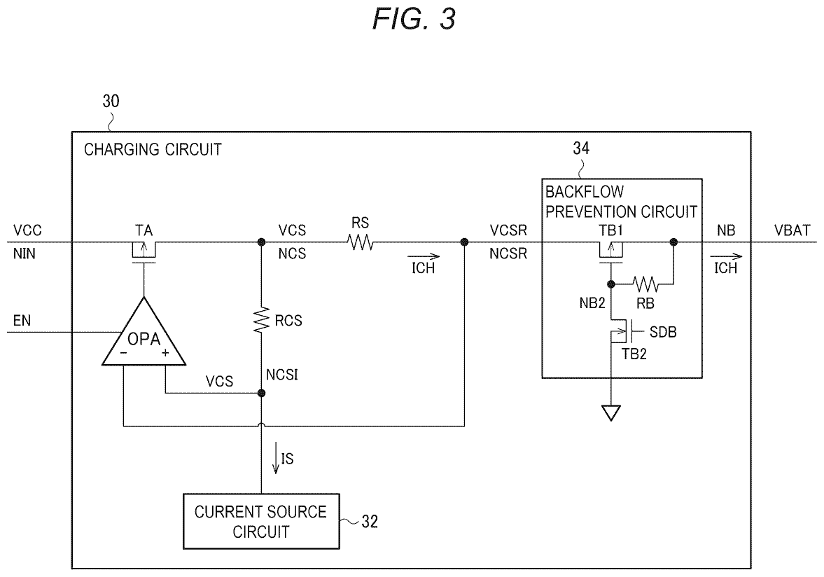

FIG. 3 shows a configuration example of the charging circuit 30. As shown in FIG. 3, the charging circuit 30 includes a current source circuit 32, an amplifier circuit OPA, a reverse current protection circuit 34, a transistor TA, and resistors RCS, RS. The amplifier circuit OPA can also be called an operational amplifier. Note that the charging circuit 30 is not limited to the configuration shown in FIG. 3, but it is possible to adopt a variety of modified implementations such as elimination of some of the elements or addition of other elements.

The current source circuit 32 outputs an output current IS based on a reference voltage. The output current IS is a current source current generated by a current source circuit 32. The output current IS is supplied to a non-inverting input terminal of the amplifier circuit OPA and a node NCS at a drain side of the P-type transistor TA. Then, based on the output current IS, the charging current ICH is generated by the amplifier circuit OPA, the transistor TA, and the resistors RS, RCS.

A source of the transistor TA is coupled to the power supply node NIN, and a drain thereof is coupled to the node NCS. The power supply voltage VCC is supplied to the power supply node NIN. The resistor RCS is disposed between the node NCS and a node NCSI. The resistor RS is disposed between the node NCS and a node NCSR. In the amplifier circuit OPA, a non-inverting input terminal is coupled to the node NCSI, an inverting input terminal is coupled to the node NCSR, and an output terminal is coupled to a gate of the transistor TA. An operation of the amplifier circuit OPA is enabled when an enable signal EN is at a low level. Accordingly, the charging current ICH (=(RCS/RS)×IS) is supplied to the node NCSR, and is supplied as the charging current ICH to the node NB which is the charging node.

The reverse current protection circuit 34 includes a P-type transistor TB1, an N-type transistor TB2, and a resistor RB. In the transistor TB1, a source is coupled to the node NB and a drain is coupled to the node NCSR. In the N-type transistor TB2, a source is coupled to a ground node and a drain is coupled to a node NB2 of a gate of the transistor TB1. The resistor RB is disposed between the node NB and the node NB2.

When starting charging the battery 10, the control circuit 50 turns on the transistor TB2 with a control signal SDB. Accordingly, the transistor TB1 is also turned on, the charging current ICH flows from the node NCSR to the node NB, and the battery 10 is charged. When ending charging the battery 10, the control circuit 50 turns off the transistor TB2 with the control signal SDB. Accordingly, the transistor TB1 is also turned off, and the reverse current protection circuit 34 prevents the reverse current of a charge from the battery 10 to the charging circuit 30.

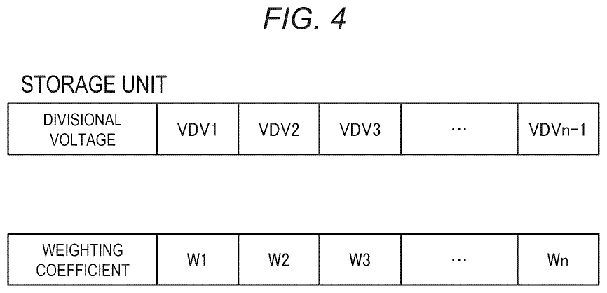

FIG. 4 is a diagram illustrating storing of the setting information of the voltage sections and the weighting coefficients into the storage unit 60. In FIG. 4, the storage unit 60 stores divisional voltages VDV1, VDV2, VDV3, . . . , and VDVn−1 corresponding to boundary voltages of the voltage sections as the setting information of the voltage sections. The character n is an integer no smaller than 2. Further, the storage unit 60 also stores the weighting coefficients W1, W2, W3, . . . , and Wn set for the voltage sections. These setting information and weighting coefficients in the voltage sections are stored in, for example, the nonvolatile memory 64, and are loaded from the nonvolatile memory 64 into the register unit 62 during the operation of the circuit device 20. Then, the control circuit 50 obtains the charge capacity of the battery 10 by performing weighting coefficient integration processing and so on based on the setting information of the voltage sections and the weighting coefficients loaded into the register unit 62.

### 2. Weighting Coefficient Integration Processing

For example, as a method of a comparative example of the present embodiment, there is a method of using a component such as a Coulomb counter which is an IC for measuring charges entering and exiting the battery in order to obtain the charge capacity of the battery. For example, in the method of the comparative example, whether the battery capacity is consumed 100% is determined using the Coulomb counter to update the cycle time. However, in this method of the comparative example, a component such as a Coulomb counter is required in addition to the circuit device for charging, which hinders a reduction in size and a reduction in cost of the electronic apparatus.

For example, in a small electronic apparatus such as an earphone, since the number of components that can be mounted is limited due to a restriction of a housing, there is when a component such as a Coulomb counter that measures charges cannot be mounted. In such a case, for example, in a small electronic apparatus that can be used all day long on a full charge, there is a method of incrementing the cycle time by to update the cycle time when the battery voltage reaches the full charge voltage during charging on the assumption of “charging once a day”.

In addition, as a charger for a small electronic apparatus as a small device, a charging case of a portable type incorporating a battery may be attached in some cases so as to be able to perform mobile charging. In such a case, there is a use case in which the small electronic apparatus is used for several hours and is then housed in the charging case. However, in the method of updating the cycle time when the full charge voltage is reached during charging, the full charge voltage may be reached many times in a day in some cases, and there is a problem that update processing of the cycle time does not match actual use.

Therefore, in the present embodiment, a plurality of threshold values (divisional voltages) are set in advance for the voltage of a battery such as a secondary battery, and weighting of the battery capacity is set to a voltage section (voltage range) sectioned by the threshold values thus set. Then, the charge capacity of the battery is obtained based on the integrated value of the weighting coefficients which are the weighting of the battery capacity. Further, when the integrated value of the weighting coefficients becomes 1 corresponding to the charge capacity of 100% while repeating charging of the battery, the cycle time is updated by incrementing the cycle time by one. In addition, the internal resistance is measured during charging so that an influence of the voltage drop due to the internal resistance of the battery is eliminated, evaluation can be performed with a voltage corresponding to the open voltage of the battery when advancing the integration of the weighting coefficients. That is, the charge capacity of the battery charged is simply obtained within the components of the circuit device (IC) as a charging device without using other measurement components such as a Coulomb counter so as to be suitable for actual use, and whether the battery capacity is consumed, for example, 100% is determined. Further, in the determination, a simulated open voltage of the battery that can be calculated by measuring the internal resistance of the battery and the resistance of the charging path is used. This makes it possible to cope with an increase in internal resistance caused by deterioration of the battery. As described above, in the present embodiment, the charge capacity of the battery is simply obtained and it is determined that the battery capacity is consumed 100% by the circuit device alone as the charging device without requiring a special charge measurement component. Accordingly, it becomes possible to perform the update processing of the cycle time which matches the actual use.

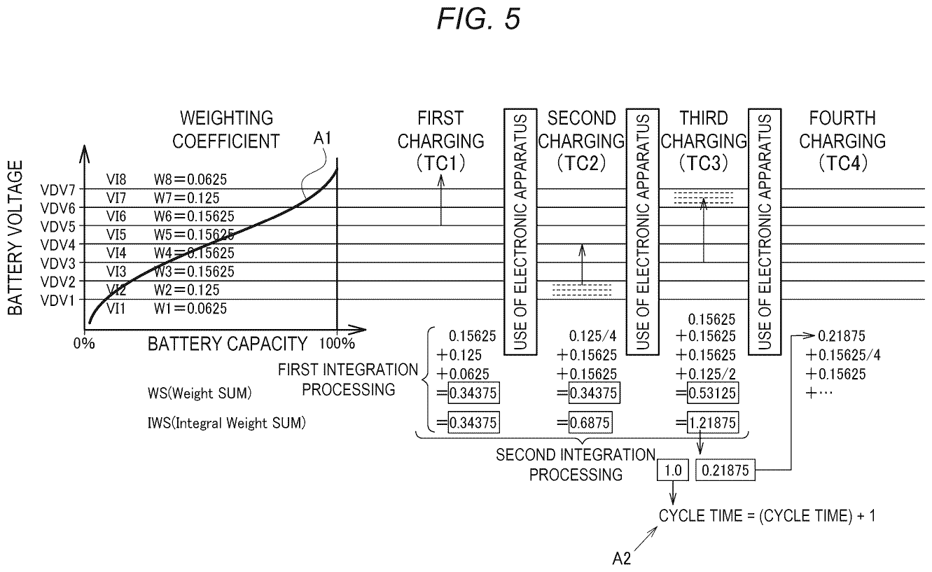

Then, a method of the present embodiment will be described in detail with reference to FIG. 5. In FIG. 5, a change section of the battery voltage VBAT is divided into a plurality of voltage sections VI1 to VI8. The voltage sections VI1 to VI8 correspond to, for example, a first voltage section to an n-th voltage section. Specifically, as described in FIG. 4, such voltage sections VI1 to VI8 are set by the divisional voltages VDV1 to VDV7 stored in the storage unit 60. For example, the divisional voltage VDV1 is a threshold voltage for setting a boundary between the voltage section VI1 and the voltage section VI2, and the divisional voltage VDV2 is a threshold voltage for setting a boundary between the voltage section VI2 and the voltage section VI3. The same applies to the other divisional voltages VDV3 to VDV7. Note that in FIG. 5, the voltage sections VI1 to VI8 are voltage sections at regular intervals, but may be voltage sections not at regular intervals.

Further, the weighting coefficients W1 to W8 are set for the voltage sections VI1 to VI8. That is, as described in FIG. 4, the weighting coefficients W1 to W8 stored in the storage unit 60 are set as the weighting in the voltage sections VI1 to VI8. The weighting coefficient is set in accordance with a charging characteristic which is a characteristic of battery-voltage to battery-capacity represented by A1 in FIG. 5. For example, when the battery capacity when fully charged is defined as 1.0 which corresponds to 100%, the weighting coefficient in the voltage section VI1 is set to W1=0.0625. This means that 6.25% of the battery capacity is charged in the voltage section VI1. Further, the weighting coefficient in the voltage section VI2 is set to W2=0.125, which means that 12.5% of the battery capacity is charged in the voltage section VI2. Further, the weighting coefficients in the voltage sections VI3 to VI6 are set to W3=W4=W5=W6=0.15625, which means that 15.625% of the battery capacity is charged in each of the voltage sections VI3 to VI6. The weighting coefficients in the voltage sections VI7, VI8 are also set by substantially the same method.

Further, in FIG. 5, in a first charging period TC1, the battery voltage VBAT changes from a voltage corresponding to the divisional voltage VDV5 to the fully charged voltage. Therefore, in this case, first integration processing of integrating the weighting coefficients W6=0.15625, W7=0.125, and W8=0.0625 in the voltage sections VI6, VI7, and VI8 is performed, and 0.15625+0.125+0.0625=0.34375 is obtained as a weight SUM (WS). WS=0.34375 means that the charge capacity is 34.375% of the battery capacity when fully charged. Further, the WS=0.34375 thus obtained is written and held in, for example, the register unit 62 in FIG. 2. As described above, the register unit 62 is a discharging-system circuit that operates using the battery voltage VBAT as the power supply voltage. Therefore, even in a state in which the electronic apparatus 2 is removed from the charging case or the charging stand having the power transmission device 14 and the power is not received from the power transmission device 14, the register unit 62 can hold WS=0.34375. Note that it is also possible to write and hold WS in the nonvolatile memory 64, but when the allowable number of times of rewriting the nonvolatile memory 64 is small, it is desirable to write WS in the register unit 62.

Then, after the first charging period TC1, the electronic apparatus 2 such as an earphone is removed from, for example, the charging case or the charging stand, and is then used by a user. This lowers the battery voltage VBAT from the fully charged voltage to the voltage in the voltage section VI2. Then, in a second charging period TC2 subsequent thereto, the battery voltage VBAT changes from the voltage in the voltage section VI2 to a voltage corresponding to the divisional voltage VDV4. In this case, the first integration processing of integrating 0.125/4 which is obtained by multiplying the weighting coefficient W2=0.125 in the voltage section VI2 by ¼ and the weighting coefficients W3=0.15625 and W4=0.15625 in the voltage sections VI3, VI4 is performed, and 0.125/4+0.15625+0.15625=0.34375 is obtained as WS. Then, second integration processing of integrating WS=0.34375, which is the integrated value of the weighting coefficients in the first charging period TC1, and WS=0.34375, which is the integrated value of the weighting coefficients in the second charging period TC2, is performed to obtain an integral weight SUM (IWS)=0.6875. Note that the IWS in the first charging period TC1 is 0.34375. WS=0.34375 and IWS=0.6875 are written and held in the register unit 62. Since the register unit 62 is the discharging-system circuit that operates using the battery voltage VBAT as the power supply voltage, the register unit 62 can hold WS=0.34375 and IWS=0.6875 even after the power reception from the power transmission device 14 stops.

Then, after the second charging period TC2, the electronic apparatus 2 is removed from the charging case or the charging stand, and is used by the user. This lowers the battery voltage VBAT from a voltage corresponding to the divisional voltage VDV4 to a voltage corresponding to the divisional voltage VDV3. Then, in a third charging period TC3 subsequent thereto, the battery voltage VBAT changes from the voltage corresponding to the divisional voltage VDV3 to a voltage within the voltage section VI7. In this case, the first integration processing of integrating the weighting coefficients W4=0.15625, W5=0.15625, and W6=0.15625 in the voltage sections VI4, VI5, and VI6 and 0.125/2 which is obtained by multiplying the weighting coefficient W7=0.125 in the voltage section VI7 by ½ is performed, and 0.15625+0.15625+0.15625+0.125/2=0.53125 is obtained as WS. Then, the second integration processing of integrating WS=0.53125 in the third charging period TC3 to IWS=0.6875 up to the second charging period TC2, and IWS=1.21875 is obtained.

Here, ISW=1.0 corresponds to 100% representing full charge. Therefore, the IWS no smaller than 1.0 means that charging of at least 100% corresponding to the full charge or more has been performed by the first, second, and third charging. Therefore, as represented by A2 in FIG. 5, the cycle time is updated by being incremented by one, and the cycle time updated is written to the nonvolatile memory 64. Then, 0.21875 out of IWS=1.21875 is set as an initial value of the integration processing in the fourth charging period TC4 subsequent thereto. In this way, it becomes possible to update the cycle time corresponding to the number of times of charging on condition that the battery capacity is charged 100% corresponding to the full charge. In addition, by writing the cycle time in the nonvolatile memory 64, it becomes possible to hold information on the cycle time even when, for example, the battery 10 is completely discharged.

For example, as a method of a comparative example of the present embodiment, there is a method of disposing a component for charge measurement such as a Coulomb counter between the circuit device 20 and the battery 10, but in this method, the number of components increases, which hinders a reduction in size and a reduction in cost of the electronic apparatus 2. In contrast, in the present embodiment, since the charge capacity is obtained using the weighting coefficients stored in the storage unit 60, the component for the charge measurement such as a Coulomb counter is unnecessary, and it is possible to realize the reduction in size and the reduction in cost of the electronic apparatus 2.

Further, there is also a method of obtaining the charge capacity of the battery 10 by measuring the charging time and the charging current value in each of the voltage sections and obtaining the product of the charging time and the charging current value thus measured. However, in this method, it becomes necessary to measure the charging time and the charging current and calculate the product thereof, and the processing load on the circuit device 20 increases. In contrast, in the present embodiment, since the weighting coefficients corresponding to the battery capacity in the respective voltage sections are stored in the storage unit 60 and the charge capacity of the battery 10 is obtained by the integration processing of the weighting coefficients, it becomes possible to realize a reduction in processing load on the circuit device 20, a reduction in power consumption, and so on.

In addition, in the method in which the cycle time is updated by being incremented by one when the battery voltage VBAT reaches the full charge voltage during charging under the assumption of charging once a day, the accurate cycle time cannot be obtained in, for example, the use case illustrated in FIG. 5. In contrast, in the present embodiment, as shown in FIG. 5, since the cycle time is updated when the integrated value of the weighting coefficients of the battery capacity becomes 1 or more, the accurate measurement of the cycle time becomes possible.

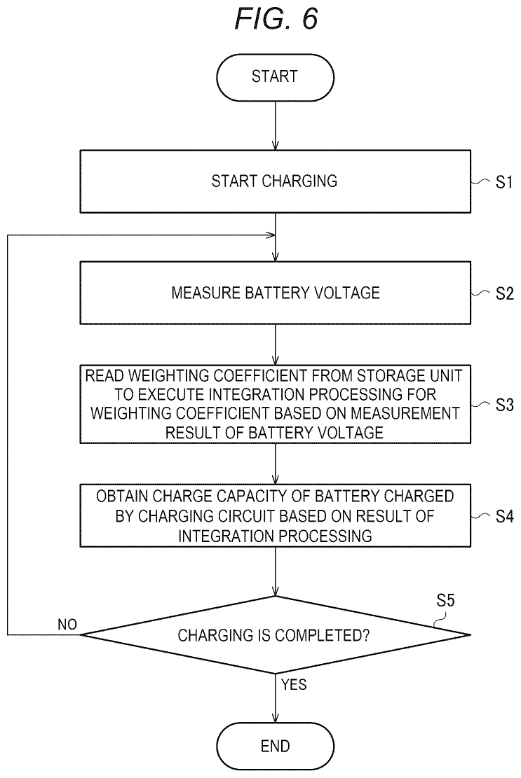

FIG. 6 is a flowchart illustrating operations of the present embodiment. When the electronic apparatus 2 is installed in the charging case, the charging stand, or the like and charging of the battery 10 is started, the voltage measurement circuit 40 measures the battery voltage VBAT (steps S1, S2). For example, the analog-digital conversion circuit 42 of the voltage measurement circuit 40 performs the analog-digital conversion of the battery voltage VBAT to output digital data of the battery voltage VBAT to the control circuit 50. Then, the control circuit 50 reads the weighting coefficient from the storage unit 60 based on the measurement result (digital data of VBAT) of the battery voltage VBAT, and performs integration processing for the weighting coefficient (step S3). Citing FIG. 5 as an example, in the first charging period TC1, the weighting coefficients W6, W7, and W8 in the voltage sections VI6, VI7, and VI8 are read, and the integration processing is performed on the weighting coefficients W6, W7, and W8. In the second charging period TC2, the weighting coefficients W2, W3, and W4 in the voltage sections VI2, VI3, and VI4 are read, and the integration processing is performed on the weighting coefficients W2, W3, and W4. The same applies to the third and fourth charging periods TC3, TC4. Note that the integration processing for the weighting coefficients may include not only the first integration processing for the weighting coefficients in each of the charging periods but also the second integration processing for the weighting coefficients in a plurality of charging periods.

Then, based on the result of the integration processing for the weighting coefficients, the control circuit 50 obtains the charge capacity of the battery 10 charged by the charging circuit 30 (step S4). In this case, such update processing of the cycle time as described in FIG. 5 may be performed based on the charge capacity thus obtained, or notification processing such as displaying the charge capacity of the battery 10 on the display unit of the electronic apparatus 2 or giving notice of the charge capacity with a sound or the like may be performed. Then, whether charging has ended is determined (step S5), and when the charging has not ended, the process returns to step S2, and when the charging has ended, the process ends.

As described above, the circuit device 20 in the present embodiment includes the charging circuit 30 that charges the battery 10, the voltage measurement circuit 40 that measures the battery voltage VBAT, and the storage unit 60 that stores the weighting coefficient for the battery capacity in each of the plurality of voltage sections. For example, the charging circuit 30 in FIGS. 1 and 2 charges the battery 10, and the voltage measurement circuit 40 measures the battery voltage VBAT of the node NB coupled to the battery 10 and outputs the measurement result to the control circuit 50. Further, as described in FIG. 4, the storage unit 60 stores the weighting coefficient of the battery capacity associated with each of the voltage sections. Further, the circuit device 20 includes the control circuit 50, and the control circuit 50 performs the integration processing on the weighting coefficients based on the measurement result of the battery voltage VBAT by the voltage measurement circuit 40, and obtains the charge capacity of the battery 10 charged by the charging circuit 30 based on the result of the integration processing. For example, as described in FIG. 5, the control circuit 50 reads, from the storage unit 60, the weighting coefficient in the voltage section to which the battery voltage VBAT changing in the charging period belongs. Then, for example, the charge capacity of the battery 10 charged in the charging period is obtained by performing the integration processing of the weighting coefficients thus read.

In this way, it becomes possible to obtain the charge capacity of the battery 10 charged by the charging circuit 30 by performing the integration processing of the weighting coefficients stored in the storage unit 60 without providing the charge measurement component outside the circuit device 20. In addition, for example, it is not required to perform processing of measuring the charging time and the charging current and obtaining the product of the charging time and the charging current, and it becomes possible to obtain the charge capacity with processing low in load for reading the weighting coefficients from the storage unit 60 and integrating the weighting coefficients. In addition, by storing the weighting coefficients corresponding to the charging characteristic of the battery 10 in advance in the storage unit 60, it is possible to more accurately obtain the charge capacity with processing low in load.

Further, the control circuit 50 performs the first integration processing of integrating the weighting coefficients in the voltage sections in the charging period as the integration processing for the weighting coefficients. Citing FIG. 5 as an example, as the first integration processing, the integration processing of the weighting coefficients W6, W7, and W8 in the voltage sections VI6, VI7, and VI8 is performed in the charging period TC1, and the integration processing of the weighting coefficients W2, W3, and W4 in the voltage sections V12, V13, and V14 is performed in the charging period TC2. Further, in the charging period TC3, the integration processing of the weighting coefficients W4, W5, W6, and W7 in the voltage sections VI4, VI5, VI6, and VI7 is performed.

In this way, for example, by performing the integration processing of the weighting coefficient in the voltage section to which the battery voltage VBAT changing in the charging period belongs, the charge capacity of the battery 10 charged in the charging period can be obtained by the processing low in load.

Further, the plurality of voltage sections is the first voltage section to the n-th voltage section obtained by dividing the change section of the battery voltage VBAT. Here, the character n is an integer no smaller than 2. Citing FIG. 5 as an example, the first voltage section to the n-th voltage section are voltage sections VI1 to VI8. Note that the number of voltage sections is not limited to eight as illustrated in FIG. 5, and may be any number. Further, it is assumed that the battery voltage VBAT at the start of charging belongs to an i-th voltage section out of the first voltage section to the n-th voltage section, and the battery voltage VBAT at the end of charging belongs to a j-th voltage section out of the first voltage section to the n-th voltage section. Here, i is an integer satisfying 1≤i≤n−1, and j is an integer satisfying i≤j≤n. In this case, the control circuit 50 performs the first integration processing using the weighting coefficients in the i-th voltage section to the j-th voltage section. Citing FIG. 5 as an example, in the charging period TC1, since the i-th voltage section is the voltage section VI6 and the j-th voltage section is the voltage section VI8, the first integration processing using the weighting coefficients W6 to W8 in the voltage sections VI6 to VI8 is performed. In the charging period TC2, since the i-th voltage section is the voltage section VI2 and the j-th voltage section is the voltage section VI4, the first integration processing using the weighting coefficients W2 to W4 in the voltage sections VI2 to VI4 is performed. Further, in the charging period TC3, since the i-th voltage section is the voltage section VI4 and the j-th voltage section is the voltage section VI7, the first integration processing using the weighting coefficients W4 to W7 in the voltage sections VI4 to VI7 is performed.

In this way, by performing the first integration processing using the weighting coefficients in the i-th voltage section to the j-th voltage section when the battery voltage VBAT changes from the voltage in the i-th voltage section at the start of charging to the voltage in the j-th voltage section at the end of charging due to charging of the battery 10 in the charging period, it becomes possible to obtain the charge capacity of the battery 10 in that charging period. Therefore, it becomes possible to obtain the charge capacity of the battery 10 in the charging period with a simple processing of measuring the battery voltage VBAT from the start of charging to the end of charging in the charging period, and reading the weighting coefficients in the i-th voltage section to the j-th voltage section corresponding thereto to perform the integration processing.

Note that when the battery voltage VBAT is a voltage within the voltage section, it is possible to perform the first integration processing of multiplying the weighting coefficient in the voltage section by the interpolation coefficient corresponding to the voltage ratio of the battery voltage VBAT within the voltage section to perform the integration. Citing FIG. 5 as an example, in the charging period TC2, the weighting coefficient W2 in the voltage section VI2 is multiplied by ¼ which is the interpolation coefficient corresponding to the voltage ratio of the battery voltage VBAT within the voltage section VI2. Further, in the charging period TC3, the weighting coefficient W7 in the voltage section VI7 is multiplied by ½ which is the interpolation coefficient corresponding to the voltage ratio of the battery voltage VBAT within the voltage section VI7.

Further, the control circuit 50 performs the second integration processing of integrating the first integration processing in each of the plurality of charging periods as the integration processing for the weighting coefficients. Citing FIG. 5 as an example, the second integration processing of obtaining IWS=0.6875 by integrating WS=0.34375, which is a result of the first integration processing in the second charging period TC2, with WS=0.34375, which is a result of the first integration processing in the first charging period TC1 is performed. Further, the second integration processing of integrating WS=0.53125, which is a result of the first integration processing in the third charging period TC3, with IWS=0.6875 to obtain IWS=1.21875 is performed.

In this way, when charging is performed a plurality of times, the integrated value obtained by integrating the results of the first integration processing in a plurality of charging periods can be obtained by the second integration processing. Accordingly, it is possible to obtain the total charge capacity of the battery 10 charged in the plurality of charging periods. Further, there is an advantage that such a total charge capacity can be obtained by processing low in load of integrating the results of the first integration processing.

Further, the control circuit 50 performs the update processing of the cycle time of the battery 10 based on a result of the second integration processing. Citing FIG. 5 as an example, IWS=1.21875 is obtained by the second integration processing of integrating the results of the first integration processing in the plurality of charging periods TC1 to TC3. In this case, based on IWS=1.21875, which is the result of the second integration processing, an update processing of incrementing the cycle time by one is performed as represented by A2.

In this way, the cycle time is updated using the integrated value obtained by integrating the results of the first integration processing in the plurality of charging periods. Accordingly, it becomes possible to update the cycle time using the total charge capacity of the battery 10 charged in the plurality of charging periods. In addition, there is an advantage that the update of the cycle time can be realized by the processing low in load of using the integrated value obtained by integrating the results of the first integration processing.

Further, when the battery voltage VBAT at the end of charging belongs to the j-th voltage section out of the first voltage section to the n-th voltage section, the control circuit 50 may perform the integration processing using the weighting coefficients from the first voltage section to the j-th voltage section. Here, j is an integer satisfying 1≤j≤n. Citing FIG. 5 as an example, in the first charging period TC1, when the battery voltage at the end of charging belongs to the voltage section VI8 (j-th voltage section), the integration processing of the weighting coefficients W1 to W8 in the voltage sections VI1 to VI8 (first voltage section to j-th voltage section) is performed. In this way, the charge capacity of the battery 10 at the end of charging in the charging period TC1 can be obtained, and it becomes possible to display the charge capacity (remaining charge amount) on, for example, a display unit of the electronic apparatus 2. Similarly, in the second charging period TC2, when the battery voltage at the end of charging belongs to the voltage section VI4, the integration processing of the weighting coefficients W1 to W4 in the voltage sections VI1 to VI4 is performed. In addition, in the third charging period TC3, when the battery voltage at the end of charging belongs to the voltage section V17, the integration processing of the weighting coefficients W1 to W7 in the voltage sections VI1 to VI7 is performed.

In this way, the charge capacity of the battery 10 at the end of charging can be obtained by measuring the battery voltage VBAT at the end of charging, and reading the weighting coefficients from the first voltage section to the j-th voltage section from the storage unit 60 to perform the integration processing. Then, by performing notification processing such as display processing on the display unit based on the charge capacity thus obtained, it becomes possible to obtain the charge capacity with the processing light in load of reading and then integrating the weighting coefficients, and then notify the user or the like of the charge capacity thus obtained.

In addition, the storage unit 60 stores the information for setting the plurality of voltage sections and information of the weighting coefficients in the respective voltage sections. Citing FIG. 4 as an example, the divisional voltages VDV1 to VDVn−1 which are the boundary voltages of the voltage sections are stored as the information for setting the voltage sections. The boundary voltage of the voltage section is a voltage representing a boundary with an adjacent voltage section, and is, for example, an upper limit voltage or a lower limit voltage of the voltage section. However, the information for setting the voltage sections is not limited to such divisional voltages, and various types of information can be used as long as the information can determine the voltage sections to which the battery voltage VBAT belongs.

In this way, it becomes possible to determine the voltage section to which the battery voltage VBAT measured belongs based on the setting information of the voltage sections read from the storage unit 60, and read the weighting coefficient in that voltage section from the storage unit 60. Further, by performing the integration processing of the weighting coefficient thus read, it becomes possible to obtain the charge capacity of the battery 10 charged by the charging circuit 30 with the processing light in processing load.

Further, the weighting coefficient is information representing a ratio of the battery capacity charged in each voltage section to, for example, the battery capacity when fully charged. Citing FIG. 5 as an example, W1=0.0625 (6.25%), which is the weighting coefficient in the voltage section VI1, is the ratio of the battery capacity charged in the voltage section VI1 to 1.0 (100%) corresponding to the battery capacity when fully charged. Further, W2=0.125 (12.5%), which is the weighting coefficient in the voltage section VI2, is the ratio of the battery capacity charged in the voltage section VI2 to 1.0 (100%) corresponding to the battery capacity when fully charged. The same applies to the weighting coefficients W3 to W8 in the voltage sections VI3 to VI8.

In this way, by performing the weighting coefficient integration processing, it becomes possible to obtain the ratio of the battery capacity charged to the battery capacity fully charged. Further, there is an advantage that the battery capacity charged can be obtained with the processing light in load of reading the weighting coefficients from the storage unit 60 and then performing the integration processing.

### 3. Measurement Of Internal Resistance

In the present embodiment, the battery voltage VBAT is measured, and the weighting coefficients are integrated based on the measurement result. However, for example, in FIG. 5, when whether the battery voltage VBAT belongs to the voltage sections VI1 to VI8 sectioned by the divisional voltages VDV1 to VDV7 is determined using the battery voltage VBAT as it is, there is a concern that a deviation occurs in the measurement.

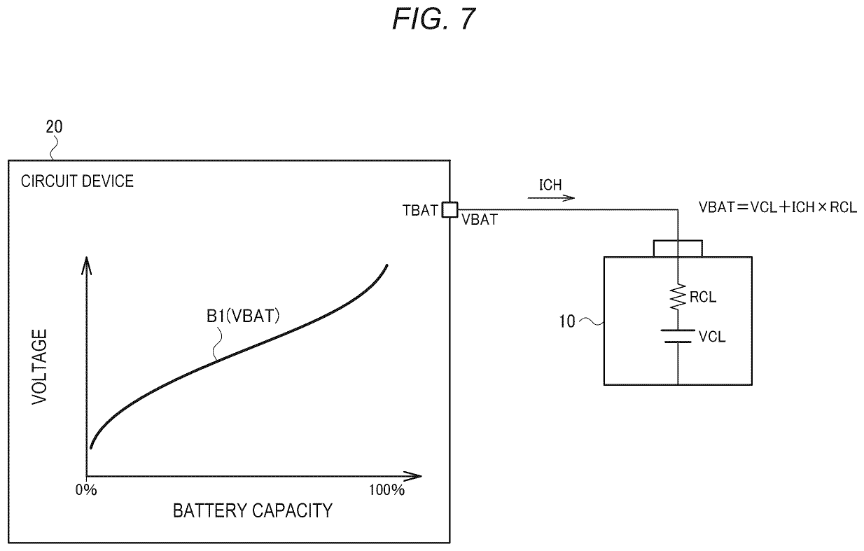

For example, FIG. 7 is a diagram illustrating the internal resistance RCL and the open voltage VCL of the battery 10. In a state where the battery 10 is charged by the charging current ICH from the circuit device 20, the battery voltage is expressed as VBAT=VCL+ICH×RCL due to a voltage drop at the internal resistance RCL. Therefore, when the measurement result of the battery voltage VBAT represented by B1 in FIG. 7 is used as it is, there is a concern that a deviation may occur in measurement by ICH×RCL with respect to the open voltage VCL of the battery 10. Further, since the internal resistance RCL tends to increase with the deterioration of the battery 10, this also causes the spread of the measurement deviation.

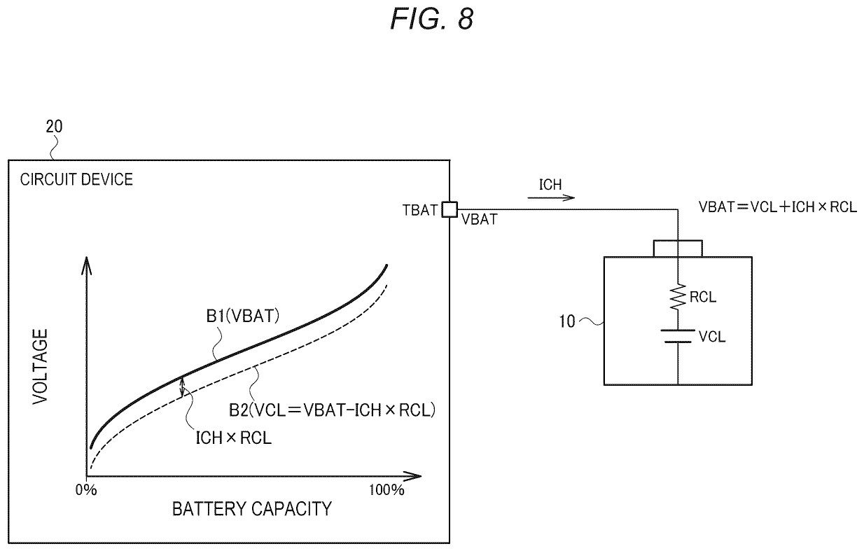

Therefore, in the present embodiment, the internal resistance RCL of the battery 10 is measured in the process in which the circuit device 20 charges the battery 10. Then, based on the internal resistance RCL thus measured, the open voltage VCL of the battery 10 is obtained using a relational expression of VCL=VBAT−ICH×RCL. In this way, it becomes possible to determine the voltage section to perform the integration processing of the weighting coefficients using the open voltage VCL obtained by lowering the battery voltage VBAT by ICH×RCL instead of the battery voltage VBAT represented by B1 in FIG. 8. Therefore, it becomes possible to obtain the charge capacity of the battery 10 using a more accurate voltage measurement result. In addition, it becomes possible to cope with an increase in the internal resistance RCL and so on due to the deterioration of the battery 10.

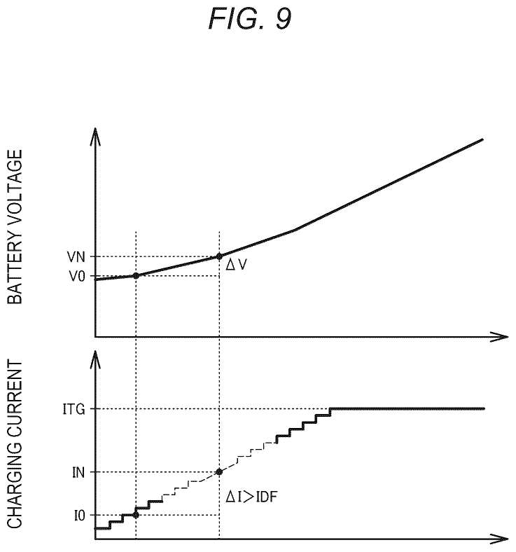

FIG. 9 is a diagram illustrating a method of measuring the internal resistance RCL. For example, in the present embodiment, in constant-current charging in the CCCV charging, the charging current is increased by stepping up the charging current to a target current value ITG. Then, the internal resistance RCL is measured in the process of increasing the charging current by stepping up the charging current. Specifically, the value of the charging current is set to I0, and the battery voltage VBAT=V0 when the value of the charging current is IC is measured. Then, the charging current is increased by stepping up the charging current from I0, and the battery voltage VBAT=VN when the value of the charging current is IN is measured. Then, when a relationship of (IN−I0)>IDF is established with respect to IDF set in advance, RCL=(ΔV/ΔI)=(VN−V0)/(IN−I0) is calculated. The value IDF is desirably set to a value corresponding to a resolution of the analog-digital conversion circuit 42 that performs analog-digital conversion on VN and V0, and is about 1 mA as an example. Then, the value of the internal resistance RCL is updated by repeatedly performing the processing described above from when setting IC to when calculating RCL until the value of the charging current reaches the target current value ITG. Then, the open voltage VCL is obtained using the internal resistance RCL finally obtained.

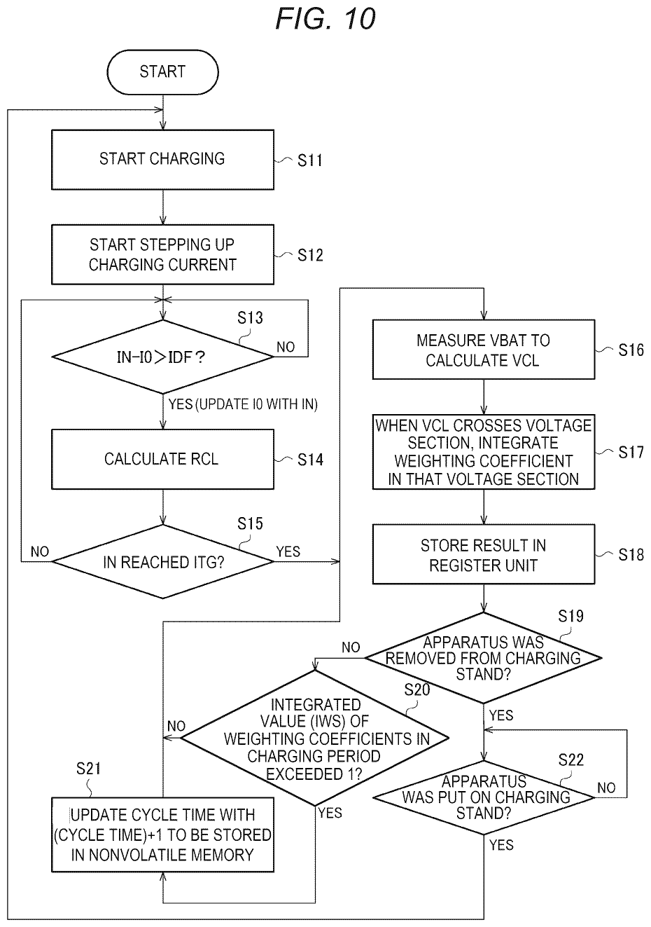

FIG. 10 is a flowchart illustrating detailed operations in the present embodiment. First, when the electronic apparatus 2 is put on a charging stand and charging is started, stepping-up of the charging current is started (steps S11, S12). For example, when the battery 10 is charged with the power received in a non-contact manner as illustrated in FIG. 2, when constant-current charging with the target current value is started without stepping up the charging current, appropriate charging cannot be performed due to a drop in the power supply voltage VCC or the like. Therefore, in the present embodiment, the constant-current charging is performed after stepping up the charging current to change the charging current value to the target current value ITG.

Then, as described with reference to FIG. 9, whether the relationship of (IN−I0)>IDF is established is determined using I0, IN, and IDF thus set (step S13). Then, when (IN−I0)>IDF is achieved, the internal resistance RCL is calculated using the relational expression of RCL=(VN−V0)/(IN−I0) (step S14). The value of the internal resistance RCL thus calculated is stored in, for example, the register unit 62. Then, whether the charging current IN has reached the target current value ITG is determined, and when the charging current IN has not reached the target current value ITG, the process returns to step S13 and the processing in steps S13, S14 is repeated. In this way, the value of the internal resistance RCL stored in the register unit 62 is updated until the charging current reaches the target current value ITG, and it becomes possible to obtain the internal resistance RCL when the charging current reaches the target current value ITG.

Then, when the charging current reaches the target current value ITG, the battery voltage VBAT is measured, and the open voltage VCL is calculated from the relational expression of VCL=VBAT−ICH×RCL (step S16). Then, when the open voltage VCL crosses the voltage section, the processing of integrating the weighting coefficient in that voltage section is performed, and the result of the integration processing is stored in the register unit 62 (steps S17, S18). Then, whether the electronic apparatus 2 has been removed from the charging stand is determined, and when the electronic apparatus 2 has not been removed, whether the IWS, which is the integrated value of the weighting coefficients in the charging period, has exceeded 1 is determined (steps S19, S20). When IWS exceeds 1, the cycle time is updated by being incremented by one as described by A2 in FIG. 5, and is stored in the nonvolatile memory 64 (step S21), and the process returns to step S16. When IWS does not exceed 1, the process returns to step S16 without updating the cycle time. On the other hand, when it is determined that the electronic apparatus 2 has been removed from the charging stand in step S19, whether the electronic apparatus 2 is put on the charging stand is determined (step S22), and when the electronic apparatus 2 is put on the charging stand, the process returns to step S11 to start charging.

As described above, in the present embodiment, the control circuit 50 obtains the internal resistance RCL of the battery 10 based on the battery voltage VBAT=V0 which is measured when the charging current value of the charging circuit 30 is the first current value IC and the battery voltage VBAT=VN which is measured when the charging current value is the second current value IN. Then, the control circuit 50 corrects the battery voltage VBAT based on the internal resistance RCL and the charging current value of the charging circuit 30 thus obtained to obtain the open voltage VCL of the battery 10. For example, the control circuit 50 corrects the battery voltage VBAT by the relational expression VCL=VBAT−ICH×RCL to obtain the open voltage VCL. Then, the control circuit 50 performs the integration processing for the weighting coefficient in the voltage section to which the open voltage VCL belongs. That is, the integration processing of the weighting coefficients described in FIGS. 1 to 6 is performed using the open voltage VCL, which is the battery voltage VBAT when the battery 10 is in the open state.

In this way, it becomes possible to measure the internal resistance RCL of the battery 10 and the resistance in the charging path to obtain the charge capacity of the battery 10 using the weighting coefficients based on the simulated open voltage VCL of the battery 10. Therefore, it becomes possible to more accurately measure the charge capacity and the cycle time. Further, it becomes possible to cope with problems such as an increase in the internal resistance RCL due to the deterioration of the battery 10.

Further, when changing the charging current value to the target current value ITG of the constant-current charging, the control circuit 50 sets the charging current value in the middle of changing to the target current value ITG to the first current value I0 and the second current value IN. For example, as shown in FIG. 9, when the charging current value is stepped up to the target current value ITG, the charging current value in the middle thereof is set to the first current value I0 and the second current value IN. Then, the internal resistance RCL of the battery 10 is obtained based on the first current value I0, the second current value IN, and the battery voltages V0, VN measured when the charging current value is the first current value I0 and the second current value IN, respectively.

In this way, in the charging control in which the constant-current charging is performed after the charging current value is changed to the target current value ITG, it becomes possible to obtain the internal resistance RCL using the first current value IC and the second current value IN which are charging current values in the middle of changing to the target current value ITG. For example, when the battery voltage when the charging current value is the first current value IC is VBAT=V0 and the battery voltage when the charging current value is the second current value IN is VBAT=VN, the internal resistance RCL can be obtained by the relational expression RCL=(VN−V0)/(IN−IC). Then, by performing the constant-current charging after the charging current value changes to the target current value ITG, it becomes possible to perform appropriate charging control when the battery 10 is charged based on the power received in, for example, a contactless manner.

Further, the control circuit 50 repeatedly obtains and updates the internal resistance RCL until the charging current value reaches the target current value ITG. For example, as represented by steps S13, S14, and S15 in FIG. 10, the processing of obtaining the internal resistance RCL by the relational expression of RCL=(VN−V0)/(IN−I0) when (IN−I0)>IDF is true is repeated until IN, which is the charging current value, reaches the target current value ITG, and the value of the internal resistance RCL stored in the register unit 62 is updated. Then, the value of the internal resistance RCL when the charging current value reaches the target current value ITG is set as the final internal resistance value, and the open voltage VCL is obtained based on the internal resistance RCL.

In this way, it becomes possible to use the value of the internal resistance RCL, which is the value when the charging current value reaches the target current value ITG of the constant-current charging, and is obtained from the first current value I0 and the second current value IN, as the internal resistance value for obtaining the open voltage VCL. Therefore, it becomes possible to obtain the charge capacity of the battery 10 by integrating the weighting coefficients based on the appropriate open voltage VCL using a value of the constant current when the constant current with the target current value ITG is made to flow in the constant-current charging. Therefore, it becomes possible to more accurately measure the charge capacity and the cycle time.

As described above, the circuit device according to the present embodiment includes a charging circuit configured to charge a battery, a voltage measurement circuit configured to measure a battery voltage of the battery, and a storage unit configured to store weighting coefficients with respect to a battery capacity in respective voltage sections of a plurality of voltage sections. Further, the circuit device includes a control circuit configured to perform integration processing on the weighting coefficient based on a measurement result of the battery voltage by the voltage measurement circuit and obtain a charge capacity of the battery charged by the charging circuit based on a result of the integration processing.

According to the present embodiment, the battery is charged by the charging circuit, and the battery voltage is measured by the voltage measurement circuit. Then, the storage unit stores the weighting coefficient for the battery capacity in each voltage section, and the control circuit performs the integration processing for the weighting coefficient based on the measurement result of the battery voltage to obtain the charge capacity of the battery based on the result of the integration processing. With this configuration, it becomes possible to obtain the charge capacity of the battery charged by the charging circuit by performing the integration processing of the weighting coefficients stored in the storage unit without providing a charge measurement component outside the circuit device. Further, it becomes possible to obtain the charge capacity with the processing light in load by storing the weighting coefficients regarding the charging characteristic in advance in the storage unit.

Further, in the present embodiment, the control circuit may perform, as the integration processing, first integration processing of integrating the weighting coefficients in the voltage sections in a charging period.

In this way, it becomes possible to obtain the charge capacity of the battery charged in the charging period with the processing light in load by performing the integration processing of the weighting coefficient in the voltage section to which the battery voltage belongs.

Further, in the present embodiment, the plurality of voltage sections may be a first voltage section to an n-th voltage section obtained by dividing a change section of the battery voltage. Further, when the battery voltage at a start of charging belongs to an i-th voltage section out of the first voltage section to the n-th voltage section and the battery voltage at an end of charging belongs to a j-th voltage section out of the first voltage section to the n-th voltage section, the control circuit may perform the first integration processing using the weighting coefficients from the i-th voltage section to the j-th voltage section. Here, n is an integer no smaller than 2, i is an integer satisfying 1≤i≤n−1, and j is an integer satisfying i≤j≤n.

In this way, by performing the first integration processing using the weighting coefficients in the i-th voltage section to the j-th voltage section when the battery voltage changes from the voltage in the i-th voltage section at the start of charging to the voltage in the j-th voltage section at the end of charging due to charging of the battery in the charging period, it becomes possible to obtain the charge capacity of the battery in that charging period.

Further, in the present embodiment, the control circuit may perform, as the integration processing, second integration processing of integrating results of the first integration processing in respective charging periods of a plurality of charging periods.

In this way, when charging is performed a plurality of times, it becomes possible to obtain, with the second integration processing, the integrated value obtained by integrating the results of the first integration processing in the plurality of charging periods.

Further, the control circuit may perform update processing of a cycle time of the battery based on a result of the second integration processing.

In this way, the cycle time becomes to be updated using the integrated value obtained by integrating the results of the first integration processing in the plurality of charging periods, and it becomes possible to update the cycle time using a total charge capacity of the battery charged in the plurality of charging periods.

Further, in the present embodiment, the plurality of voltage sections may be a first voltage section to an n-th voltage section obtained by dividing a change section of the battery voltage. Further, when the battery voltage at the end of charging belongs to the j-th voltage section out of the first voltage section to the n-th voltage section, the control circuit may perform the integration processing using the weighting coefficients from the first voltage section to the j-th voltage section. Here, n is an integer no smaller than 2, and j is an integer satisfying 1≤j≤n.

In this way, the charge capacity of the battery at the end of charging can be obtained by measuring the battery voltage at the end of charging, and reading the weighting coefficients from the first voltage section to the j-th voltage section from the storage unit to perform the integration processing.

In addition, the storage unit may store the information for setting the plurality of voltage sections and information of the weighting coefficients in the respective voltage sections.

In this way, it becomes possible to determine the voltage section to which the battery voltage measured belongs based on the setting information of the voltage sections read from the storage unit, and read the weighting coefficient in that voltage section from the storage unit.

Further, the weighting coefficient may be information representing a ratio of the battery capacity charged in each voltage section to the battery capacity when fully charged.

In this way, by performing the weighting coefficient integration processing, it becomes possible to obtain the ratio of the battery capacity charged to the battery capacity fully charged.

Further, the control circuit may obtain an internal resistance of the battery based on the battery voltage measured by the voltage measurement circuit when a charging current value of the charging circuit is a first current value and the battery voltage measured by the voltage measurement circuit when the charging current value is a second current value. Further, the control circuit may correct the battery voltage based on the internal resistance and the charging current value of the charging circuit to obtain an open voltage of the battery, and perform the integration processing with the weighting coefficient for the voltage section to which the open voltage belongs.

In this way, it becomes possible to measure the internal resistance or the like of the battery to obtain the charge capacity of the battery using the weighting coefficient based on the open voltage of the battery.

Further, when changing the charging current value to a target current value of constant-current charging, the control circuit may set the charging current value in a middle of changing to the target current value to the first current value and the second current value.

In this way, in the charging control in which the constant-current charging is performed after the charging current value is changed to the target current value, it becomes possible to obtain the internal resistance using the first current value and the second current value which are charging current values in the middle of changing to the target current value.

Further, the control circuit may repeatedly obtain and update the internal resistance until the charging current value reaches the target current value.

In this way, it becomes possible to use the value of the internal resistance, which is the value when the charging current value reaches the target current value of the constant-current charging, and is obtained from the first current value and the second current value, as the internal resistance value for obtaining the open voltage.

Further, an electronic apparatus according to the present embodiment includes the circuit device and a battery.

Note that although the present embodiment is described in detail above, those skilled in the art should easily understand that many modifications can be made without substantially departing from the novel matters and the advantages of the present disclosure. Accordingly, all such modifications should be within the scope of the present disclosure. For example, a term described at least once in the specification or the drawings along with a different term broader or the same in meaning can be replaced with that different term anywhere in the specification and the drawings. Further, all combinations of the present embodiment and the modifications are also included in the scope of the present disclosure. Further, the configurations, operations, and so on of the circuit device and the electronic apparatus are not limited to those described in the present embodiment, and various modifications can be made thereon.

What is claimed is:

1. A circuit device comprising:
a charging circuit configured to charge a battery;
a voltage measurement circuit configured to measure a battery voltage of the battery;
a storage unit configured to store weighting coefficients for a battery capacity in respective voltage sections of a plurality of voltage sections; and
a control circuit configured to perform integration processing on the weighting coefficients based on a measurement result of the battery voltage by the voltage measurement circuit, and obtain a charge capacity of the battery charged by the charging circuit based on a result of the integration processing.

2. The circuit device according to claim 1, wherein
the control circuit performs, as the integration processing, first integration processing of integrating the weighting coefficients in the voltage sections in a charging period.

3. The circuit device according to claim 2, wherein
the plurality of voltage sections are a first voltage section to an n-th voltage section (n is an integer no smaller than 2) obtained by dividing a change section of the battery voltage, and
the control circuit performs the first integration processing using the weighting coefficients from an i-th voltage section (i is an integer satisfying 1≤i≤n−1) to a j-th voltage section (j is an integer satisfying i≤j≤n) when the battery voltage at a start of the charging belongs to the i-th voltage section out of the first voltage section to the n-th voltage section and the battery voltage at an end of the charging belongs to the j-th voltage section out of the first voltage section to the n-th voltage section.

4. The circuit device according to claim 2, wherein
the control circuit performs, as the integration processing, second integration processing of integrating results of the first integration processing in respective charging periods of a plurality of charging periods.

5. The circuit device according to claim 4, wherein
the control circuit performs update processing of a cycle time of the battery based on a result of the second integration processing.

6. The circuit device according to claim 1, wherein
the plurality of voltage sections are a first voltage section to an n-th voltage section (n is an integer no smaller than 2) obtained by dividing a change section of the battery voltage, and
the control circuit performs the integration processing using the weighting coefficients from the first voltage section to a j-th voltage section (j is an integer satisfying 1≤j≤n) when the battery voltage at an end of the charging belongs to the j-th voltage section out of the first voltage section to the n-th voltage section.

7. The circuit device according to claim 1, wherein
the storage unit stores information for setting the plurality of voltage sections and information of the weighting coefficients in the respective voltage sections.

8. The circuit device according to claim 1, wherein
the weighting coefficient is information representing a ratio of a battery capacity charged in each of the voltage sections to a battery capacity when fully charged.

9. The circuit device according to claim 1, wherein
the control circuit
obtains an internal resistance of the battery based on the battery voltage measured by the voltage measurement circuit when a charging current value of the charging circuit is a first current value and the battery voltage measured by the voltage measurement circuit when the charging current value is a second current value,
corrects the battery voltage based on the internal resistance and the charging current value of the charging circuit to obtain an open voltage of the battery, and
performs the integration processing using the weighting coefficient for the voltage section to which the open voltage belongs.

10. The circuit device according to claim 9, wherein
the control circuit sets the charging current value in a middle of changing to the target current value to the first current value and the second current value when changing the charging current value to a target current value of constant-current charging.

11. The circuit device according to claim 10, wherein
the control circuit repeatedly obtains and updates the internal resistance until the charging current value reaches the target current value.

12. An electronic apparatus comprising:
the circuit device according to claim 1; and
the battery.
